(19) United States
(12) Patent Application Publication
(10) Pub. No.: US 2025/0041895 A1
(43) Pub. Date: Feb. 6, 2025

(54) Apparatus for coating a strip-shaped substrate with a Parylene layer

(71) Applicant: Fraunhofer-Gesellschaft zur Förderung der angewandten Forschung e.V., Munich (DE)

(72) Inventors: Emmy Törker, Dresden (DE); Franz Selbmann, Chemnitz (DE); Michiel Top, Dresden (DE)

(73) Assignee: Fraunhofer-Gesellschaft zur Förderung der angewandten Forschung e.V., Munich (DE)

(21) Appl. No.: 18/743,172

(22) Filed: Jun. 14, 2024

Related U.S. Application Data
(63) Continuation of application No. PCT/EP2022/078632, filed on Oct. 14, 2022.

(30) Foreign Application Priority Data
Dec. 17, 2021 (DE) 10 2021 133 627.9

(51) Int. Cl. B05C 13/02; B05C 9/14

(52) U.S. Cl. CPC B05C 13/02; B05C 9/14

(57) ABSTRACT

An apparatus is provided for coating a strip-shaped substrate with a parylene layer within a working chamber, comprising a take-off roller for unwinding the strip-shaped substrate; a take-up roller for winding the strip-shaped substrate after the coating process; a processing roller, with which the strip-shaped substrate can be led past a coating zone; a first housing, which delimits the coating zone; a second housing delimiting the first housing, as a result of which the second housing delimits a volume between the first housing and the second housing; at least one inlet which extends through a wall of the first housing and by means of which at least one monomer-containing gas for depositing the parylene layer can be introduced into the coating zone; and at least one pumping means, by means of which a negative pressure can be generated in the volume between the first housing and the second housing.

### CROSS-REFERENCE TO RELATED APPLICATIONS

This application is a continuation of PCT/EP2022/078632 filed Oct. 14, 2022, which claims priority under 35 USC § 119 to German patent application DE 10 2021 133 627.9 filed Dec. 17, 2021. The entire contents of each of the above-identified applications are hereby incorporated by reference.

### BRIEF DESCRIPTION OF THE DRAWINGS

The embodiments may be better understood with reference to the following drawings and description. The components in the figures are not necessarily to scale. Moreover, in the FIGURES, like-referenced numerals designate corresponding parts throughout the different views.

FIG. 1 shows an apparatus according to the invention in a schematic representation

### DETAILED DESCRIPTION

The invention relates to an apparatus for coating a strip-shaped substrate with a parylene layer within a working chamber.

Parylene is the name for a group of polymers and can be formed in different variants, which are characterized, for example, by good barrier properties, high chemical resistance, and/or a low coefficient of friction, which is why parylene layers are often used as cover layers, for example in objects from medical technology, electronics, or aerospace.

Parylene layers are typically deposited on the surface of substrates using chemical vapor deposition techniques. Here, a solid and powdery to granular starting material called a dimer is first heated under vacuum conditions and sublimated into a gas. The gas is then subjected to pyrolysis and thereby broken down into reactive, monomeric components. Finally, the monomer components are often deposited on a substrate at room temperature. Such a procedure is described, for example, in U.S. Pat. No. 8,889,224 B2.

The deposition of parylene layers on substrates is established, for example, in so-called batch systems, as shown, for example, in WO 2007/003489 A1. Here, at least one substrate to be coated is introduced into a working chamber, the working chamber is closed, and at least one monomer-containing gas is admitted into the working chamber, which is deposited on the surface of the substrate by polymerization. After layer deposition, the working chamber is ventilated and at least one substrate is removed from the working chamber. The apparatuses known from WO 2007/003489 A1 can also have a cold trap, with which unreacted monomer molecules that are still present in the working chamber or in the gas outlet after the layer deposition and before the working chamber is ventilated, can be separated. A disadvantage of coating substrates by means of chemical vapor deposition in general and thus also of the previously described procedures for depositing parylene layers is that the monomer introduced into a working chamber is deposited not only on the substrate but also on all other unprotected surfaces within the working chamber.

In addition to other technical problems, such as maintaining the vacuum when passing a strip-shaped substrate through a working chamber, the apparatuses described above are therefore not suitable for coating strip-shaped substrates either, because, when passing a strip-shaped substrate of this kind through the working chamber of a known batch system, the rear face of the substrate is also coated with parylene, which is not desired in most applications.

An apparatus in which a gas with parylene monomers is provided and passed through a nozzle is known from DE 10 2010 010 819 A1. The parylene monomers are deposited on the surface of a substrate, which is moved past the nozzle opening. Such a system is therefore also suitable for coating strip-shaped substrates which are moved past the nozzle opening. However, even with an apparatus of this kind, the disadvantage remains that parylene also deposits on all other unprotected surfaces within a working chamber and thus also on the rear face of the substrate to be coated, unless protective measures are provided against it.

The invention is therefore based on the technical problem of creating an apparatus for coating a strip-shaped substrate with a parylene layer, by means of which the disadvantages of the prior art can be overcome. In particular, the apparatus according to the invention is intended to enable the coating of strip-shaped substrates in a roll-to-roll process within a working chamber and to protect the interior walls of the working chamber and the side of the strip-shaped substrates that is not to be coated from being coated with parylene.

An apparatus according to the invention for coating a strip-shaped substrate with a parylene layer within a working chamber comprises firstly a take-off roller for unwinding the strip-shaped substrate; a take-up roller for winding the strip-shaped substrate after the coating process; a processing roller, which is partially wrapped around the strip-shaped substrate, by means of which the strip-shaped substrate can be guided past a coating zone. According to the invention, an apparatus further comprises a first housing which delimits the coating zone and which has a first opening, which is directed toward the substrate, wherein the first opening is enclosed by a first opening edge; a second housing which has a second opening, which is directed toward the substrate, wherein the second opening is enclosed by a second opening edge and wherein the second housing delimits the first housing, as a result of which the second housing delimits a volume between the first housing and the second housing; at least one inlet, which extends through a wall of the first housing and by means of which at least one monomer-containing gas for depositing the parylene layer can be introduced into the coating zone, and at least one pumping means, by means of which a negative pressure can be generated in the volume between the first housing and the second housing. The term monomer-containing gas is understood to mean all gases comprising monomer molecules known from prior art that are suitable for depositing a parylene layer by means of chemical vapor deposition.

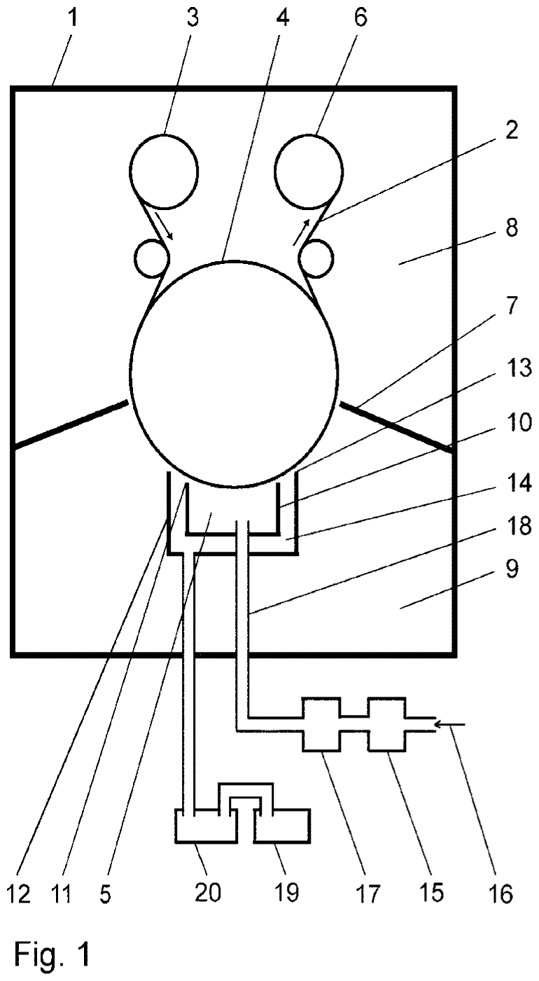

The invention is explained in more detail below using an exemplary embodiment. FIG. 1 shows an apparatus according to the invention in a schematic representation.

The apparatus according to the invention according to FIG. 1 comprises a working chamber 1, within which a strip-shaped substrate 2 to be coated is initially wound onto a take-off roller 3. The strip-shaped substrate 2 is to be coated on one side with a parylene layer. For this purpose, the strip-shaped substrate is unwound from the take-off roller 3 and guided over a processing roller 4 in such a way that the strip-shaped substrate 2 partially wraps around the processing roller 4, wherein the strip-shaped substrate 2 is guided past a coating zone 5 by means of the processing roller 4. After a coating process, the strip-shaped substrate 2 is wound onto a take-up roller 6. An apparatus according to the invention can also have one or more deflection rollers, by means of which the strip-shaped substrate 2 can be guided through the working chamber 1 and/or past one or more other coating stations, which can be located upstream and/or downstream of the coating zone 5.

Intermediate walls 7 divide the interior of the working chamber 1 into a winding chamber 8, in which, for example, atmospheric conditions can be formed, and a processing chamber 9, in which a pressure of greater than 10 Pa is set, wherein the take-off roller 3 and the take-up roller 6 are located in the winding chamber 8 and the coating zone 5 is formed within the processing chamber 9. The processing roller 4 extends into both the winding chamber 8 and the processing chamber 9. For efficient layer deposition, it is advisable that the substrate is not heated too much during parylene layer deposition. Therefore, in one embodiment of the invention, the processing roller 4 is a cooling cylinder or cooling roller and is dimensioned with regard to its cooling parameters such that the substrate 2 is not heated to temperatures above 45° C. during the parylene layer deposition.

A first housing 10 arranged within the processing chamber 9, which delimits the coating zone 5, has a first opening which is aligned toward the portion of the substrate 2, which partially wraps around the processing roller 4, wherein the first opening is delimited and thus also limited by a first opening edge 11 of the first housing 10.

The apparatus according to the invention from FIG. 1 further comprises a second housing 12, which has a second opening, which is also aligned toward the section of the substrate 2, which partially wraps around the processing roller 4, wherein the second opening is enclosed and thus also delimited by a second opening edge 13 of the second housing 12, and wherein the second housing 12 delimits the first housing 10, as a result of which the second housing 12 delimits a volume 14 between the first housing 10 and the second housing 12.

Furthermore, an apparatus according to the invention can also comprise means for providing at least one monomer for depositing a parylene layer, as are known from prior art. For this purpose, the apparatus according to the invention shown in FIG. 1 comprises an evaporator means 15, into which powdered or granular dimer 16 is introduced as parylene starting material, heated at a pressure of less than 10 Pa and at a temperature greater than 80° C. and consequently sublimated into a gas. The gas is fed to a pyrolysis means 17 and split into monomers at a pressure of less than 10 Pa and a temperature of greater than 550° C. The monomers, in turn, are introduced into the coating zone 5 by means of at least one inlet 18, which extends through a wall of the second housing 12 and a wall of the first housing 10, in such a way that a pressure of less than 10 Pa is set within the first housing 10. Under these pressure conditions, the monomer molecules within the coating zone 5 are deposited by polymerization on the face of the substrate 2, which is facing away from the processing roller 4. This face of the strip-shaped substrate 2 is also referred to in the following as the front face of the substrate 2, whereas the side of the strip-shaped substrate 2, which faces the processing roller 4 and abuts the processing roller 4, is also referred to as the rear face of the substrate 2.

In the embodiment according to FIG. 1, only one evaporator means 15 is shown. Alternatively, an apparatus according to the invention can also comprise several evaporator means 15, which are operated, for example, in parallel in such a way that a continuous supply of the monomer-containing gas into the coating zone 5 is ensured.

As a further component of an apparatus according to the invention, a pumping means 19 is shown in FIG. 1, by means of which a negative pressure can be generated in the volume 14 between the first housing 10 and the second housing 12. The pumping means 19 is dimensioned such that it can be used to set a pressure that corresponds to a maximum of 80% of the pressure set within the first housing 10. In a preferred embodiment, a pressure, which corresponds to 70% to 80% of the pressure within the first housing 10 in the volume 14, can be set by means of the pumping means 19. In the described embodiment, a pressure of less than 8 Pa is set in volume 14. The monomer molecules which do not deposit on the substrate 2 within the coating zone 5 and pass into the volume 14 through the gap between the substrate 2 and the first opening edge 11 are thus pumped out of the volume 14 by means of the pumping means 19. By means of the pumping means 19 it can be ensured that no monomer molecules or only a negligible proportion of monomer molecules enter the space inside the processing chamber 9 and outside the second housing 12 and do not form any undesirable harmful deposits there.

In order to maintain the aforementioned pressure conditions as well as ensure that as few monomer molecules as possible enter the volume 14 or the space inside the processing chamber 9 and outside the second housing 12, it is advantageous to design the distance between the substrate 2 and the first opening edge 11 and the distance between the substrate 2 and the second opening edge 13 as small as possible. In a further preferred embodiment of the invention, the first opening edge 11 of the first housing 10 and the second opening edge 13 of the second housing 12 are therefore each spaced apart from the substrate 2 by a maximum of 3 mm.

In a further embodiment, the mouth opening of the at least one inlet 18 is spaced apart from the substrate by a distance of at least 20 mm so that a sufficient distribution of the monomer-containing gas within the coating zone 5 can be ensured for a homogeneous coating of the substrate 2. In order to support a distribution of the monomer-containing gas within the coating zone 5, at least one baffle plate can additionally be arranged in front of the mouth opening of the at least one inlet 18, wherein the baffle plate can, for example, be oriented such that the directional beam of the monomer-containing gas flowing into the coating zone 5 corresponds to the normal of the surface of the baffle plate. In this case, the distance between the baffle plate and the mouth opening of the at least one inlet 18 can be, for example, 5 mm to 15 mm.

To protect the pumping means 19 so that no monomers settle on the walls within the pumping means 19 and thereby damage the pumping means 19 it is advantageous if, in the flow channel, at least one cold trap 20 is arranged between the volume 14 and the pumping device 19, by means of which cold trap condensable components of the gas pumped out of the volume 14 are filtered out before the pumped gas reaches the pumping means 19. In a cold trap 20 of this kind known from prior art, a temperature of less than −40° C. is preferably set.

As a further optional element, an apparatus according to the invention can also have at least one heating element, with which the first housing 10 and/or the second housing 12 can be heated to a temperature greater than 45° C. This also reduces the possibility of undesirable damaging coating of the first housing 10 or the second housing 12. The at least one heating element can be designed, for example, as a resistance heating element which is attached to the first housing 10 or the second housing 12 and in which the heat is generated on the basis of the flow of an electric current.

In the embodiment according to FIG. 1 it was described that the working chamber 1 has intermediate walls 7, with which the working chamber 1 is divided into a winding chamber 8 and a processing chamber 9. However, the intermediate walls 7 are an optional element of the invention. What is essential to the invention is only that the pressure outside the second housing 12 is greater than the pressure in the volume 14. In an alternative embodiment, the working chamber 1 has no intermediate walls 7, so that identical pressure conditions prevail in the entire area inside the working chamber 1 and outside the second housing 12. However, the disadvantage here is that larger pumping means or more pumping means, which must maintain the required pressure conditions outside the second housing 12 if a negative pressure is to be generated outside the housing 12, are required for the area outside the second housing 12.

In principle, a parylene layer can also be deposited on a strip-shaped substrate 2 within a working chamber 1 if the working chamber 1 does not have a second housing 12 and thus has no volume 14 separated with respect to the pressure conditions. A disadvantage of such an apparatus, however, is that all remaining surfaces within the working chamber 1 and outside the first housing 10 are provided with an undesirable damaging coating and larger or more pumping means are also required in order to maintain the required pressure conditions outside the first housing 10 if a negative pressure is to be generated in the area outside the first housing 10.

As previously shown, an apparatus according to the invention is suitable for depositing a parylene layer on a strip-shaped substrate even in a roll-to-roll process. Because the rear face of the strip-shaped substrate abuts a processing roller during the coating process, no parylene particles can be deposited on the rear face of the substrate either. Furthermore, the pressure stage system, which is formed by means of the first and second housing within the processing chamber, prevents parasitic parylene layers from depositing on the interior walls of the working chamber or on processing means arranged within the working chamber.

To clarify the use of and to hereby provide notice to the public, the phrases “at least one of <A>, <B>, . . . and <N>” or “at least one of <A>, <B>, . . . or <N>” or “at least one of <A>, <B>, . . . <N>, or combinations thereof” or “<A>, <B>, . . . and/or <N>” are defined by the Applicant in the broadest sense, superseding any other implied definitions hereinbefore or hereinafter unless expressly asserted by the Applicant to the contrary, to mean one or more elements selected from the group comprising A, B, . . . and N. In other words, the phrases mean any combination of one or more of the elements A, B, . . . or N including any one element alone or the one element in combination with one or more of the other elements which may also include, in combination, additional elements not listed. Unless otherwise indicated or the context suggests otherwise, as used herein, “a” or “an” means “at least one” or “one or more.”

1. An apparatus for coating a strip-shaped substrate with a parylene layer within a working chamber, comprising:
a take-off roller for unwinding the strip-shaped substrate;
a take-up roller for winding the strip-shaped substrate after the coating process;
a processing roller, which is partially wrapped around the strip-shaped substrate and by means of which the strip-shaped substrate can be guided past a coating zone;
a first housing, which delimits the coating zone and which has a first opening which is directed toward the substrate, and wherein the first opening is delimited by a first opening edge;
a second housing having a second opening directed toward the substrate, wherein the second opening is surrounded by a second opening edge and wherein the second housing delimits the first housing, as a result of which the second housing defines a volume between the first housing and the second housing;
at least one inlet, which extends through a wall of the first housing and by means of which at least one monomer-containing gas can be introduced into the coating zone for depositing the parylene layer; and
at least one pumping means, by means of which a negative pressure can be generated in the volume between the first housing and the second housing.

2. The apparatus of claim 1, wherein the first opening edge of the first housing and the second opening edge of the second housing are each spaced apart from the substrate by a maximum of 3 mm.

3. The apparatus according of claim 1, wherein the mouth opening of the at least one inlet is at least 20 mm apart from the substrate.

4. The apparatus of claim 1, wherein the working chamber has a processing chamber, within which the coating zone is formed.

5. The apparatus of claim 4, wherein a pressure greater than 10 Pa is set within the processing chamber.

6. The apparatus of claim 1, wherein a pressure of less than 10 Pa is set within the first housing.

7. The apparatus of claim 1, wherein a pressure is set in the volume between the first housing and the second housing, which corresponds to a maximum of 80% of the pressure set within the first housing.

8. The apparatus of claim 1, wherein, in the flow channel, at least one cold trap is arranged between the volume and the at least one pumping means.

9. The apparatus of claim 1, wherein the processing roller is a cooling cylinder or cooling roller.

10. The apparatus of claim 1, characterized by at least one heating element by means of which the first housing 10 and/or the second housing 12 can be heated to a temperature greater than 45° C.
